(19) United States
(12) Patent Application Publication
(10) Pub. No.: US 2017/0307716 A1
(43) Pub. Date: Oct. 26, 2017

(54) PROPELLER MR IMAGING WITH ARTEFACT SUPPRESSION

(71) Applicant: KONINKLIJKE PHILIPS N.V., EINDHOVEN (NL)

(72) Inventor: ELWIN DE WEERDT, EINDHOVEN (NL)

(21) Appl. No.: 15/516,423

(22) PCT Filed: Oct. 6, 2015
(86) PCT No.: PCT/EP2015/073027

§ 371 Date: Apr. 3, 2017

(30) Foreign Application Priority Data
Oct. 10, 2014 (EP) 14188402.3

(51) Int. Cl. G01R 33/565; G01R 33/48; G01R 33/56

(52) U.S. Cl. CPC G01R 33/56509; G01R 33/56545; G01R 33/4824; G01R 33/5608

(57) ABSTRACT

The invention relates to a method of MR imaging of a body (10) of a patient. It is an object of the invention to provide a method that enables efficient compensation of image artefacts in combination with PROPELLER imaging. The invention proposes to combine k-space blades in image space, and not in k-space like in conventional PROPELLER imaging. Local image artefacts are detected and corrected in single-blade MR images. The artefact detection and correction in the image domain prior to combining the single-blade MR images into a final MR image results in an improved image quality by better suppression of local artefacts and, thus, an increased signal-to-noise. Moreover, the invention relates to a MR device (1) and to a computer program for a MR device (1).

### FIELD OF THE INVENTION

The invention relates to the field of magnetic resonance (MR) imaging. It concerns a method of MR imaging of a portion of a body placed in the examination volume of a MR device. The invention also relates to a MR device and to a computer program to be run on a MR device.

### BACKGROUND OF THE INVENTION

Image-forming MR methods which utilize the interaction between magnetic fields and nuclear spins in order to form two-dimensional or three-dimensional images are widely used nowadays, notably in the field of medical diagnostics, because for the imaging of soft tissue they are superior to other imaging methods in many respects, do not require ionizing radiation and are usually not invasive.

According to the MR method in general, the body of the patient to be examined is arranged in a strong, uniform magnetic field B₀ whose direction at the same time defines an axis (normally the z-axis) of the co-ordinate system to which the measurement is related. The magnetic field B₀ produces different energy levels for the individual nuclear spins in dependence on the magnetic field strength which can be excited (spin resonance) by application of an electromagnetic alternating field (RF field) of defined frequency (so-called Larmor frequency, or MR frequency). From a macroscopic point of view the distribution of the individual nuclear spins produces an overall magnetization which can be deflected out of the state of equilibrium by application of an electromagnetic pulse of appropriate frequency (RF pulse) while the corresponding magnetic field B₁ of this RF pulse extends perpendicular to the z-axis, so that the magnetization performs a precessional motion about the z-axis. The precessional motion describes a surface of a cone whose angle of aperture is referred to as flip angle. The magnitude of the flip angle is dependent on the strength and the duration of the applied electromagnetic pulse. In the case of a so-called 90° pulse, the magnetization is deflected from the z axis to the transverse plane (flip angle 90°).

After termination of the RF pulse, the magnetization relaxes back to the original state of equilibrium, in which the magnetization in the z direction is built up again with a first time constant T₁ (spin lattice or longitudinal relaxation time), and the magnetization in the direction perpendicular to the z direction relaxes with a second and shorter time constant T₂ (spin-spin or transverse relaxation time). The transverse magnetization and its variation can be detected by means of receiving RF coils which are arranged and oriented within an examination volume of the MR device in such a manner that the variation of the magnetization is measured in the direction perpendicular to the z-axis. The decay of the transverse magnetization is accompanied by dephasing taking place after RF excitation caused by local magnetic field inhomogeneities facilitating a transition from an ordered state with the same signal phase to a state in which all phase angles are uniformly distributed. The dephasing can be compensated by means of a refocusing RF pulse (for example a 180° pulse). This produces an echo signal (spin echo) in the receiving coils.

It is important to note that transverse magnetization dephases also in presence of constant magnetic field gradients. This process can be reversed, similar to the formation of RF induced echoes, by appropriate gradient reversal forming a so-called gradient echo. However, in case of a gradient echo, effects of main field inhomogeneities, chemical shift and other off-resonances effects are not refocused, in contrast to the RF refocused echo.

In order to realize spatial resolution in the body, constant magnetic field gradients extending along the three main axes are superposed on the uniform magnetic field B₀, leading to a linear spatial dependency of the spin resonance frequency. The signal picked up in the receiving coils then contains components of different frequencies which can be associated with different locations in the body. The signal data obtained via the receiving coils correspond to the spatial frequency domain and are called k-space data. The k-space data usually include multiple lines acquired of different phase encoding. Each line is digitized by collecting a number of samples. A set of k-space data is converted to an MR image by means of Fourier transformation.

In a variety of MRI applications, motion of the examined patient can adversely affect image quality. Acquisition of sufficient MR signals for reconstruction of an image takes a finite period of time. Motion of the patient during that finite acquisition time typically results in motion artefacts in the reconstructed MR image. In conventional MR imaging approaches, the acquisition time can be reduced to a very small extent only, when a given resolution of the MR image is specified. In the case of medical MR imaging, motion artefacts can result for example from cardiac and respiratory cyclic motion, and other physiological processes, as well as from patient motion resulting in blurring, misregistration, deformation and ghosting artefacts.

Different approaches have been developed to overcome problems with respect to motion in MR imaging. Among these is the so-called PROPELLER imaging technique. In the PROPELLER concept (Periodically Rotated Overlapping ParalEL Lines, see James G. Pipe: “Motion Correction With PROPELLER MRI: Application to Head Motion and Free-Breathing Cardiac Imaging”, Magnetic Resonance in Medicine, vol. 42, 1999, pages 963-969), MR signal data are acquired in k-space in N strips, each consisting of L parallel k-space lines, corresponding to the L lowest frequency phase-encoding lines in a Cartesian-based k-space sampling scheme. Each strip, which is also referred to as k-space blade, is rotated in k-space by an angle of, for example, 180°/N, so that the total MR data set spans a circle in k-space. If a full k-space data matrix having a diameter M is desired, then L and N may be chosen so that L×N=M×π/2. One essential characteristic of PROPELLER is that a central circular portion in k-space, having a diameter L, is acquired for each k-space blade. This central portion can be used to reconstruct a low-resolution MR image for each k-space blade. The low-resolution MR images are compared to each other to remove in-plane displacements and phase errors, which are due to patient motion. These factors are corrected for in each k-space blade in accordance with the PROPELLER scheme. A suitable technique such as cross-correlation is employed to determine which k-space blades were acquired with significant through-plane displacement or include other types of artefacts. As the MR signal data are combined in k-space before the reconstruction of the final MR image, the MR data from k-space blades are weighted according to the artefact level detected by cross-correlating the k-space blades, so that artefacts are reduced in the final MR image. The PROPELLER technique makes use of oversampling in the central portion of k-space in order to obtain an MR image acquisition technique that is robust with respect to motion of the examined patient during MR signal acquisition. Moreover, due to the weighted averaging of k-space blades PROPELLER ‘averages out’ further imaging artefacts resulting from, for example, B₀ inhomogeneities or inaccurate coil sensitivity maps when parallel imaging techniques like SENSE are used for MR data acquisition.

However, drawbacks of the known PROPELLER approach result from the fact that image artefacts like, for example, SENSE artefacts resulting from inaccurate coil sensitivity maps (appearing as ghosts in the final MR image), flow artefacts that typically appear within a small band covering only a part of the MR image, or B₀ inhomogeneities that appear often at the air/tissue interfaces within the MR images, have only local effects in the image domain, i.e. the image artefacts appear only in restricted regions within the MR image. This leads to the conclusion that the conventional PROPELLER approach of down-weighting complete k-space blades to mitigate the effect of artefacts in the final MR image is actually costing more signal-to-noise ratio (SNR) than necessary. There is a significant amount of image information in each k-space blade which is not corrupted by image artefacts. However, this valuable information is also down-weighted, i.e. effectively “thrown away” during blade combination in k-space according to the conventional PROPELLER implementation.

### SUMMARY OF THE INVENTION

From the foregoing it is readily appreciated that there is a need for an improved MR imaging technique. It is consequently an object of the invention to provide a method that enables efficient compensation of image artefacts in combination with PROPELLER imaging.

In accordance with the invention, a method of MR imaging of a body of a patient placed in the examination volume of a MR device is disclosed. The method comprises the steps of:

a) generating MR signals by subjecting at least a portion of the body to a MR imaging sequence of at least one RF pulse and switched magnetic field gradients;
b) acquiring the MR signals as a plurality of k-space subsets, each k-space subset covering a different portion of k-space, wherein at least a part of a central portion of k-space is acquired for each k-space subset;
c) reconstructing a single-subset MR image from each k-space subset; and
d) combining the single-subset MR images into a final MR image.

Preferably, the MR imaging sequence is a PROPELLER sequence, with the k-space subsets being k-space blades that are rotated about the centre of k-space, so that the total acquired data set of MR signals spans a circle in k-space.

It is the gist of the invention to combine the k-space subsets (the k-space blades) in image space, and not in k-space like in conventional PROPELLER imaging. Local image artefacts can be effectively detected and corrected in the single-subset (single-blade) MR images according to the invention. The artefact detection and correction in the image domain before combining the subset data into the final MR image results in an improved image quality by better suppressing local artefacts and, thus, increased SNR.

Preferably, image regions containing artefacts are identified in the single-subset MR images in accordance with the invention. This may be achieved, for example, by a consistency analysis of the single-subset MR images. In the consistency analysis, voxel values of each single-subset MR image are compared to voxel values of the other single-subset MR images. In most cases, the image artefacts will be located in different regions of the single-subset MR images. This means that the voxel value at a given image position will have the correct value in most of the single-subset MR images. Defective voxels can be easily and reliably detected by the consistency analysis as it makes use of the information from all single-subset MR images. An important advantage of this approach is that all types of image artefacts are detectable in principle. Alternative options for detecting the image artefacts will be described in detail further below.

In a further preferred embodiment of the invention, the single-subset MR images are combined into the final MR image by weighted superposition of the single-subset MR images. The weighted superposition in the image domain enables an effective and targeted elimination of local image artefacts in the final MR image. The weighting factors of the weighted superposition are derived from the spatial distribution of image artefacts in the single-subset images so that local image artefacts are “masked-out” by applying a reduced weighting to the voxel values of the single-subset images in the image regions containing artefacts. The weighted superposition therein ensures that the valuable image information contained in the single-subset MR images outside the defective image regions is preserved and fully transferred into the final MR image so that an optimum SNR is obtained.

In a possible practical embodiment of the invention, a weight map, which is a map attributing a weighting factor to each image position, is computed as explained before (and optionally normalized). Each single-subset MR image is multiplied with the weight map. The thus weighted single-subset MR images are then transformed back to k-space, and the resulting modified k-space subsets are combined and reconstructed into the final MR image, like in the conventional PROPELLER scheme. Hence, superposing the single-subset MR images into the final MR image within the meaning of the invention does not necessarily imply that the superposition takes place directly in image space. Just as well, a combination of k-space representations of the (weighted) single-subset MR images may be performed in k-space, wherein the obtained combined k-space data are then reconstructed into the final MR image.

As in conventional PROPELLER imaging, the method of the invention may also comprise the step of estimating and correcting motion-induced displacements and phase errors in the k-space subsets. For example, low-resolution MR images reconstructed from the central k-space data of the k-space subsets are compared to each other to remove in-plane displacements and phase errors, which are caused by patient motion. These factors should be corrected for in each k-space subset in accordance with the invention prior to reconstructing the single-subset MR images. This renders the method of the invention robust with respect to motion of the examined patient during MR signal acquisition.

In one variant of the method of the invention, the data of the k-space subsets are combined completely in the image domain, which means, in other words, that the high-resolution final MR image is directly computed from the complete (high-resolution) single-subset MR images. Although this approach of computing the final MR image will produce the best possible image quality, the computational effort may be significantly higher than in the standard PROPELLER reconstruction scheme, i.e. with the combination of the k-space blades in k-space. Since the time-to-first-image and the total reconstruction time can be of importance for the user of a MR device, this variant of the method of the invention may not be feasible without appropriate hardware modifications that bring about a corresponding increase in computation speed.

In an alternative variant of the invention, a hybrid scheme of combining the k-space subsets may be applied such that the computational effort is almost equal to the standard PROPELLER technique. The term “hybrid” herein means using a combination of combining the subset data in k-space and in image space. To this end, the single-subset MR images may be reconstructed only from central k-space data of the k-space subsets, wherein the single-subset MR images are combined into a low-resolution MR image. This may be performed simply by computing a (weighted) average of the low-resolution single-subset MR images. Further, this variant of the method of the invention comprises the steps of: combining the k-space subsets into a full k-space dataset (as in conventional PROPELLER imaging), combining the full k-space dataset with a k-space representation of the low-resolution MR image into a combined full k-space dataset, and reconstructing the final MR image from the combined full k-space dataset. This means, in other words, that low resolution single-subset MR images are combined in image space next to the conventional PROPELLER k-space based combination of k-space subsets, wherein a key-hole technique is applied subsequently to obtain a high-resolution final MR image. The centre of the k-space data from which the final MR image is reconstructed is based on the combined low-resolution MR image, while the peripheral k-space data is based on a combination of the acquired k-space subsets directly in k-space. Because the low resolution MR image can be made artefact free while preserving the most SNR (as described above), the final high-resolution MR image will have a strongly reduced artefact level and higher SNR as compared to conventional PROPELLER images. The key advantage of this variant of the method of the invention is the low computational effort, such that the performance is comparable to conventional PROPELLER implementations.

The method of the invention described thus far can be carried out by means of a MR device including at least one main magnet coil for generating a uniform, steady magnetic field B₀ within an examination volume, a number of gradient coils for generating switched magnetic field gradients in different spatial directions within the examination volume, at least one body RF coil for generating RF pulses within the examination volume and/or for receiving MR signals from a body of a patient positioned in the examination volume, a control unit for controlling the temporal succession of RF pulses and switched magnetic field gradients, and a reconstruction unit for reconstructing MR images from the received MR signals. The method of the invention can be implemented by a corresponding programming of the reconstruction unit and/or the control unit of the MR device.

The method of the invention can be advantageously carried out on most MR devices in clinical use at present. To this end it is merely necessary to utilize a computer program by which the MR device is controlled such that it performs the above-explained method steps of the invention. The computer program may be present either on a data carrier or be present in a data network so as to be downloaded for installation in the control unit of the MR device. In one version the computer program is to be run on a MR device, which computer program comprises instructions for:

a) generating a MR imaging sequence of at least one RF pulse and switched magnetic field gradients, wherein the MR imaging sequence is a PROPELLER sequence;
b) acquiring MR signals as a plurality of k-space subsets (21-29), each k-space subset (21-29) covering a different portion of k-space, wherein at least a part of a central portion (30) of k-space is acquired for each k-space subset (21-29) with the k-space subsets (21-29) being k-space blades that are rotated about the centre of k-space, so that the total acquired data set of MR signals spans a circle in k-space;
c) reconstructing a single-subset MR image from each k-space subset (21-29) only from central k-space data of the k-space subsets (21-29), and the single-subset MR images are combined into a low-resolution MR image by the weighted superposition of the single-subset MR images according to said weighting factors;
wherein image regions containing artefacts are identified in the single-subset MR images;
deriving for a weighted superposition weighting factors from the spatial distribution of image artefacts in the single-subset images; and
d) combining the single-subset MR images into a final MR image.
In another version the computer program is to be run on a MR device, which computer program comprises instructions for:
a) generating MR signals by subjecting at least a portion of the body (10) to a MR imaging sequence of at least one RF pulse and switched magnetic field gradients; wherein the MR imaging sequence is a PROPELLER sequence,
b) acquiring the MR signals as a plurality of k-space subsets (21-29), each k-space subset (21-29) covering a different portion of k-space, wherein at least a part of a central portion (30) of k-space is acquired for each k-space subset (21-29); with the k-space subsets (21-29) being k-space blades that are rotated about the centre of k-space, so that the total acquired data set of MR signals spans a circle in k-space,
c) reconstructing a single-subset MR image from each k-space subset (21-29) wherein image regions containing artefacts are identified in the single-subset MR images; deriving for a weighted superposition weighting factors from the spatial distribution of image artefacts in the single-subset images and
d) combining the single-subset MR images into low-resolution MR image by the weighted superposition of the single-subset MR images according to said weighting factors;
e) combining the k-sapce subsets into a full k-space dataset;
f) combining the full k-space data set with a k-space representation of the low-resolution MR image into a combined full k-space data set and
g) reconstructing a final image from the combined full k-space dataset.

### BRIEF DESCRIPTION OF THE DRAWINGS

The enclosed drawings disclose preferred embodiments of the present invention. It should be understood, however, that the drawings are designed for the purpose of illustration only and not as a definition of the limits of the invention. In the drawings:

FIG. 1 shows a MR device for carrying out the method of the invention;

FIG. 2 schematically illustrates the PROPELLER acquisition scheme of the invention;

FIG. 3 shows single-blade MR images containing local image artefacts;

FIG. 4 shows a block diagram illustrating one embodiment of the method of the invention;

FIG. 5 shows a diagram of k-space illustrating the keyhole approach of the invention;

FIG. 6 shows an example of a XI map for detecting SENSE artefacts.

### DETAILED DESCRIPTION OF THE EMBODIMENTS

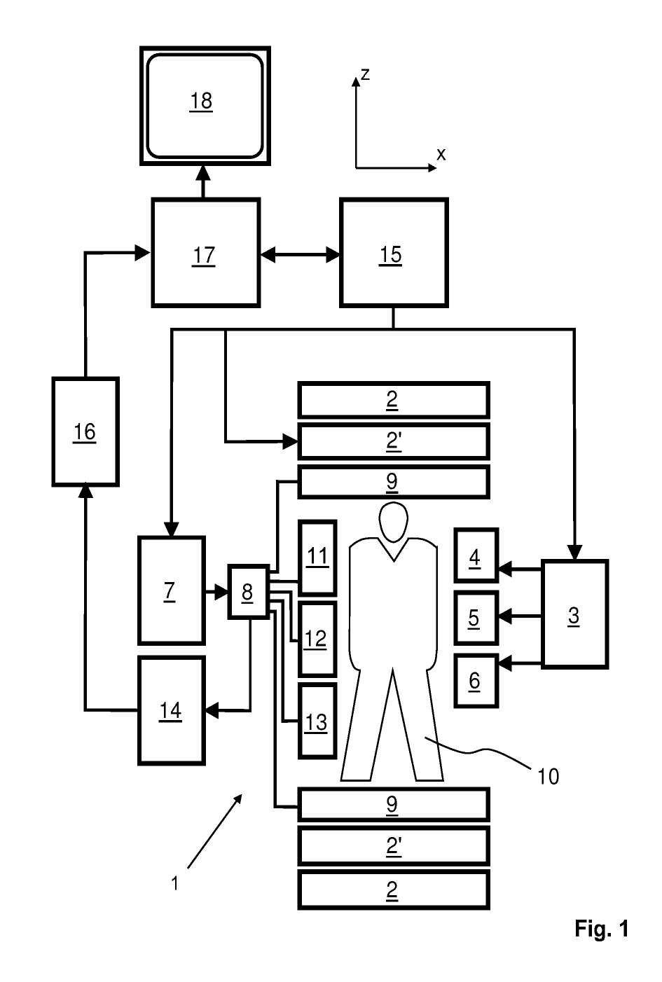

With reference to FIG. 1, a MR device 1 is shown. The device comprises superconducting or resistive main magnet coils 2 such that a substantially uniform, temporally constant main magnetic field B₀ is created along a z-axis through an examination volume. The device further comprises a set of (1^{st}, 2^{nd}, and—where applicable—3^{rd} order) shimming coils 2′, wherein the current flow through the individual shimming coils of the set 2′ is controllable for the purpose of minimizing B₀ deviations within the examination volume.

A magnetic resonance generation and manipulation system applies a series of RF pulses and switched magnetic field gradients to invert or excite nuclear magnetic spins, induce magnetic resonance, refocus magnetic resonance, manipulate magnetic resonance, spatially and otherwise encode the magnetic resonance, saturate spins, and the like to perform MR imaging.

More specifically, a gradient amplifier 3 applies current pulses or waveforms to selected ones of whole-body gradient coils 4, 5 and 6 along x, y and z-axes of the examination volume. A digital RF frequency transmitter 7 transmits RF pulses or pulse packets, via a send/receive switch 8, to a body RF coil 9 to transmit RF pulses into the examination volume. A typical MR imaging sequence is composed of a packet of RF pulse segments of short duration which, together with any applied magnetic field gradients, achieve a selected manipulation of nuclear magnetic resonance signals. The RF pulses are used to saturate, excite resonance, invert magnetization, refocus resonance, or manipulate resonance and select a portion of a body 10 positioned in the examination volume. The MR signals are also picked up by the body RF coil 9.

For generation of MR images of limited regions of the body 10 or for scan acceleration by means of parallel imaging, a set of local array RF coils 11, 12, 13 are placed contiguous to the region selected for imaging. The array coils 11, 12, 13 can be used to receive MR signals induced by body-coil RF transmissions.

The resultant MR signals are picked up by the body RF coil 9 and/or by the array RF coils 11, 12, 13 and demodulated by a receiver 14 preferably including a preamplifier (not shown). The receiver 14 is connected to the RF coils 9, 11, 12 and 13 via send/receive switch 8.

A host computer 15 controls the shimming coils 2′ as well as the gradient pulse amplifier 3 and the transmitter 7 to generate any of a plurality of MR imaging sequences, such as echo planar imaging (EPI), echo volume imaging, gradient and spin echo imaging, fast spin echo imaging, and the like. For the selected sequence, the receiver 14 receives a single or a plurality of MR data lines in rapid succession following each RF excitation pulse. A data acquisition system 16 performs analog-to-digital conversion of the received signals and converts each MR data line to a digital format suitable for further processing. In modern MR devices the data acquisition system 16 is a separate computer which is specialized in acquisition of raw image data.

Ultimately, the digital raw image data are reconstructed into an image representation by a reconstruction processor 17 which applies a Fourier transform or other appropriate reconstruction algorithms, such as SENSE or GRAPPA. The MR image may represent a planar slice through the patient, an array of parallel planar slices, a three-dimensional volume, or the like. The image is then stored in an image memory where it may be accessed for converting slices, projections, or other portions of the image representation into appropriate format for visualization, for example via a video monitor 18 which provides a man-readable display of the resultant MR image.

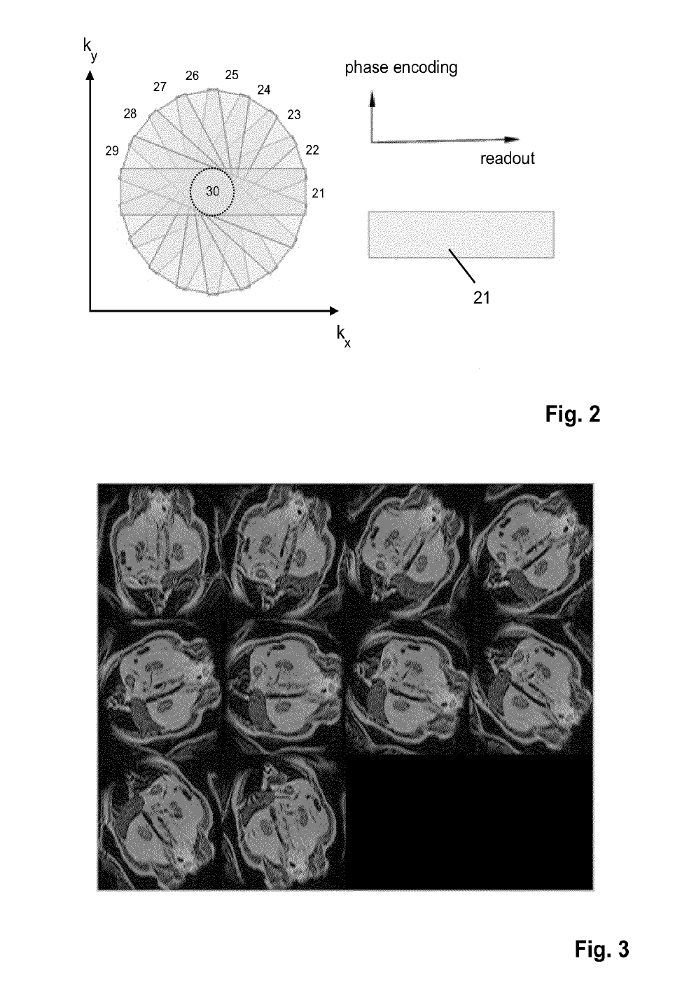

FIG. 2 illustrates the k-space sampling of PROPELLER MR imaging according to the invention. As shown in the left illustration of FIG. 2, nine k-space subsets (blades) 21-29 are acquired. Each blade 21-29 covers a different portion of k-space, wherein a central circular portion 30 of k-space is acquired for each blade 21-29. The blades 21-29 are rotated about the center of k-space, so that the total acquired MR data set spans a circle in k-space. In the right illustration of FIG. 2 a single k-space blade 21 is shown which is acquired using SENSE. The orientation of the phase encoding direction and the readout direction relative to the blade orientation is maintained for all rotation angles of the k-space blades 21-29.

FIG. 3 shows examples of eight single-subset (single-blade) MR images (one MR image is reconstructed from each blade) containing image artefacts, as indicated by the arrows. The artefacts have a local character which means that the larger part of each single-blade MR image is correct. The artefacts are located at different positions in each single-blade MR image. Hence, for a single location in the anatomy a majority of the single-blade MR images will have the correct pixel values.

According to the invention, the single-blade MR images are combined into a final MR image in image space in order to account for the local character of the image artefacts. The single-blade MR images can be combined in image space by solving a linear inverse problem. The inverse problem can be formulated as:

minₚΣᵢ₌₁^{N}∥p_{blade,i}−Aᵢp∥²

Wherein N is the number of blades, p_{blade,i}, is the vector containing the single-blade MR image pixel values, p is the vector containing the final MR image pixel values and Aᵢ is a sparse matrix reflecting the relation between the final MR image pixel values and the single-blade MR image pixel values. The A matrices can be derived using the knowledge of the k-space positions of each acquired blade. In other words, Aᵢ reflects the blade angulations and resolutions. The inverse problem is linear and, thus, convex which means that it has a unique solution and can be solved by any least squares algorithm. There are several ways of detecting the positions of the local artefacts in the single-blade MR images. Two possible techniques will be explained in detail below. Under the assumption that the information of possibly defective voxels is known for every single-blade MR image in the image domain, it can be easily incorporated into the inverse problem by extending it into a weighted inverse problem:

minₚΣᵢ₌₁^{N}∥Wᵢp_{blade,i}−WᵢAᵢp∥²

Wherein W is a diagonal weight matrix that assigns a low weight to those equations containing defective single-blade voxels.

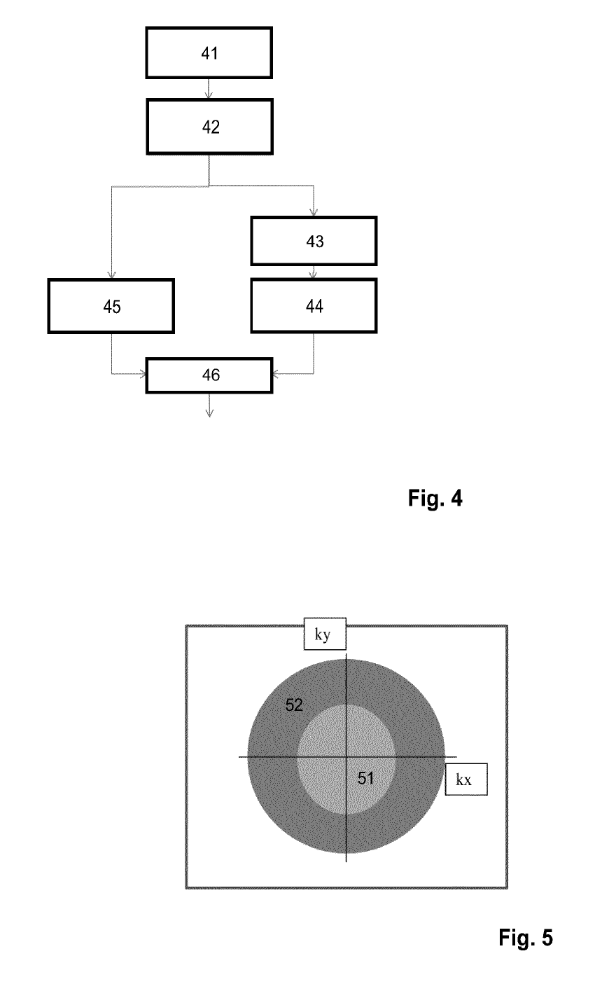

In the afore-described embodiment, the final MR image p is directly computed from the complete single-subset MR images p_{blade,i}. In an alternative embodiment, which is illustrated in FIGS. 4 and 5, a hybrid scheme of combining the blades is applied such that the computational effort is significantly reduced.

In step 41, the k-space blades are acquired as shown in FIG. 1. Motion-induced displacements and phase errors in the blades are detected and corrected in step 42 like in conventional PROPELLER imaging. Low-resolution single-blade MR images p_{blade,i} are reconstructed only from the central k-space data (portion 30, see FIG. 1) of the blades in step 43. The motion-corrected low-resolution single-blade MR images p_{blade,i} are regridded to a common grid. Once this is done, the inversion problem for weighted combination of the low-resolution single-blade MR images p_{blade,i} into a low-resolution MR image p in step 44 can be written as:

minₚΣᵢ₌₁^{N}∥Wᵢp_{blade,i}−WᵢAᵢp∥²

This inverse problem can be solved per voxel. There is no coupling between individual voxels as Wᵢ is a diagonal matrix. The solution may be derived simply by computing the weighted average of the low-resolution single-blade MR images:

$${p}_{k} = {\sum }_{i = 1}^{N} \frac{{w}_{ik} {p}_{blade , i}}{{\sum }_{j = 1}^{N} {w}_{jk}}$$

This will result in an artefact-free low resolution MR image pₖ. However, the final MR image should be a high-resolution MR image. In order to achieve this, the acquired k-space blades are combined in k-space in step 45, again like in conventional PROPELLER reconstruction. In step 46, a k-space representation of the low-resolution MR image pₖ (covering only the central portion of k-space) is combined with the full k-space data set generated in step 45. This way of combining the data corresponds to a key-hole technique as illustrated in FIG. 5. The central k-space portion 51 of the full k-space data as acquired, motion-corrected and combined in steps 41, 42, and 43 is replaced by the k-space representation of the low-resolution MR image computed in step 44. The peripheral k-space data 52 are preserved. The final high-resolution MR image is reconstructed from this combined k-space dataset. The result is a high-resolution MR image with a reduced artefact level and improved SNR.

A key feature of the scheme of the invention is the ability to detect the image regions within the single-blade MR images where artefacts are located. The image regions containing artefacts can be identified by a consistency analysis of the single-blade MR images. Two methods for detecting the defective image regions are described in the following.

The first option is to use a so-called XI map. A XI map is computed per single-blade MR image by projecting the reconstructed single-blade MR image back onto the folded image space (i.e. the image space to which the single-coil k-space blades are reconstructed prior to SENSE unfolding). Then the mean squared error of the difference between the projection and the folded single-coil/single-blade MR images mᵢⱼ is computed:

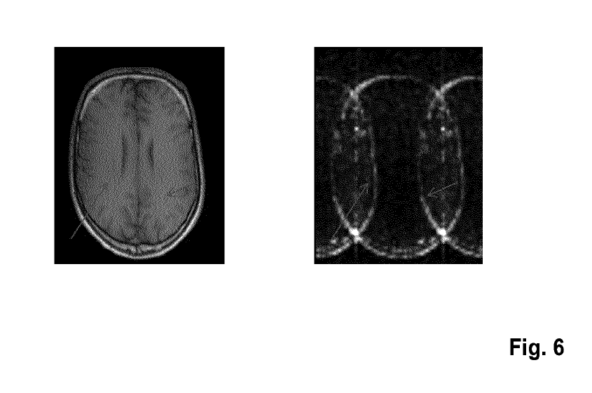

XI_{blade,i}=Σⱼ₌₁^{C}∥mᵢⱼ−Sᵢⱼp_{blade,i}∥²

Wherein C is the number of RF coils 11, 12, 13 used in the SENSE acquisition of the k-space blades, Sᵢⱼ is the SENSE encoding matrix of blade i. The XI map will “highlight” the image regions containing any inconsistencies, e.g. SENSE artefacts resulting from inaccurate coil sensitivity maps used in SENSE unfolding (see FIG. 6) or flow artefacts. This method works well in cases in which the number of coils that are sensitive in a given image region exceeds the effective acceleration factor, i.e. there is redundant image data. A benefit of this method is that the information of artefact positions is available at the resolution of the individual k-space blade, i.e. on the grid of the single-blade MR image which has a high resolution in the readout direction. A drawback of this method is that not all types of artefacts may be detected equally well.

FIG. 6 illustrates an example of a XI map and SENSE artefacts in a head scan. The left image is a SENSE reconstructed MR image containing SENSE artefacts (indicated by arrows). The right image is the corresponding XI map “highlighting” the locations of SENSE artefacts.

Another option is to use the low-resolution single-blade MR images (reconstructed from the centre portion 30 of k-space of each k-space blade). To determine which single-blade MR image contains defective voxels at a given image position, it should first be determined what the “true” voxel value must be at that position. It is known that in almost all cases the artefacts are located in different positions per single-blade MR image, which means that per image position the majority of the single-blade MR images have the correct voxel value. Hence finding the ‘true’ value can be achieved by solving the following simple problem:

minₚΣᵢ₌₁^{N}∥p_{blade,i}−p∥¹

This problem can be solved efficiently using a weighted least squares solving algorithm. The output will be the value ofp and a matrix of weights denoting which single-blade MR image contains a defective voxel value indicating an image artifact. These weights may be compared to the XI maps (see above) or may be directly used in the weighted combination of the single-blade MR images. A benefit of this method is that all artefacts are detectable in principle. A drawback is that the information is available only at low resolution. The consequence is that possibly more down-weighting will be applied during the combination of the single-blade MR images resulting in a certain amount of blurring in the final MR image.

If there are many defective voxels in the single-blade MR images, the weighted inverse problem (see above) may become ill-conditioned. To ensure that the solution represents the true anatomy, additional regularization may be needed for stabilizing the problem. This can be formulated, for example, as:

minₚΣᵢ₌₁^{N}∥Wᵢp_{blade,i}−WᵢAᵢp∥²+W_{reg}∇p∥²

Wherein W_{reg} is a weight matrix based on the knowledge of the image regions containing artefacts. ∇p is the set of spatial derivates of the solution p. If an image region is corrupted in one of the single-blade MR images, the weight is made non-zero. This effects that the solution is of lower resolution in those image regions where information is missing (because of artefacts in the single-blade MR images). In other words, the artefact level is reduced at the cost of local blurring.

1. A method of magnetic resonance (MR) imaging of a body of a patient placed in the examination volume of a MR device, the method comprising the steps of:
a) generating MR signals by subjecting at least a portion of the body to a PROPELLER MR imaging sequence of at least one RF pulse and switched magnetic field gradients;
b) acquiring the MR signals as a plurality of k-space subsets, each k-space subset covering a different portion of k-space, wherein at least a part of a central portion of k-space is acquired for each k-space subset; with the k-space subsets being k-space blades that are rotated about the centre of k-space, so that the total acquired data set of MR signals spans a circle in k-space,
c) reconstructing single-subset MR images from each k-space subset;
d) identifying image regions containing artefacts are in the single-subset MR images and deriving weighting factors from the spatial distribution of image artefacts in the single-subset images the weighting factors reducing weighting of the voxel values of the single-subset images in the image regions containing artefacts; and
e) combining the single-subset MR images into a final MR image by weighted superposition using said weighting factors of the single-subset MR images.

2. A method of MR imaging of a body of a patient placed in the examination volume of a MR device, the method comprising the steps of:
a) generating MR signals by subjecting at least a portion of the body to a PROPELLER MR imaging sequence of at least one RF pulse and switched magnetic field gradients;
b) acquiring the MR signals as a plurality of k-space subsets, each k-space subset covering a different portion of k-space, wherein at least a part of a central portion of k-space is acquired for each k-space subset; with the k-space subsets being k-space blades that are rotated about the centre of k-space, so that the total acquired data set of MR signals spans a circle in k-space,
d) reconstructing single-subset low resolution MR images from central k-space data of each k-space subset;
e) identifying image regions containing artefacts in the single-subset low resolution MR images and deriving weighting factors from the spatial distribution of image artefacts in the single-subset images the weighting factors reducing weighting to the voxel values of the single-subset images in the image regions containing artefacts;
f) combining the single-subset low resolution MR images into a low-resolution MR image by the weighted superposition of the single-subset MR images according to said weighting factors;
g) combining the k-space subsets into a full k-space dataset;
h) combining the full k-space data set with a k-space representation of the low-resolution MR image into a combined full k-space data set; and
i) reconstructing a final image from the combined full k-space dataset.

3. The method of claim 1, wherein the image regions containing artefacts are identified by a consistency analysis of the single-subset MR images.

4. The method of claim 1, wherein the weighted superposition is computed by solving a linear inverse problem.

5. The method of claim 1, comprising the step of estimating and correcting motion-induced displacements and phase errors in the k-space subsets prior to reconstructing the single-subset MR images.

6. A magnetic resonance (MR) device for carrying out the method claimed in claim 1, which MR device includes at least one main magnet coil for generating a uniform, steady magnetic field B0 within an examination volume, a number of gradient coils for generating switched magnetic field gradients in different spatial directions within the examination volume, at least one RF coil for generating RF pulses within the examination volume and/or for receiving MR signals from a body of a patient positioned in the examination volume, a control unit for controlling the temporal succession of RF pulses and switched magnetic field gradients, and a reconstruction unit for reconstructing MR images from the received MR signals, wherein the MR device is configured to perform the following steps:
a) generating MR signals by subjecting at least a portion of the body to a PROPELLER MR imaging sequence of at least one RF pulse and switched magnetic field gradients;
b) acquiring the MR signals as a plurality of k-space subsets, each k-space subset covering a different portion of k-space, wherein at least a part of a central portion of k-space is acquired for each k-space subset; with the k-space subsets being k-space blades that are rotated about the centre of k-space, so that the total acquired data set of MR signals spans a circle in k-space,
c) reconstructing single-subset low resolution MR image from central k-space data of each k-space subset;
d) identifying image regions containing artefacts are in the single-subset low resolution MR images and derive weighting factors from the spatial distribution of image artefacts in the single-subset images the weighting factors reducing weighting of the voxel values of the single-subset images in the image regions containing artefacts;
e) combining the single-subset low resolution MR images into low-resolution MR image by the weighted superposition of the single-subset MR images according to said weighting factors;
f) combining the k-space subsets into a full k-space dataset;
g) combining the full k-space data set with a k-space representation of the low-resolution MR image into a combined full k-space data set; and
h) reconstructing a final image from the combined full k-space dataset.

7. A computer program to be run on a magnetic resonance (MR) device, which computer program comprises instructions for:
a) generating MR signals by subjecting at least a portion of the body to a PROPELLER MR imaging sequence of at least one RF pulse and switched magnetic field gradients;
b) acquiring the MR signals as a plurality of k-space subsets, each k-space subset covering a different portion of k-space, wherein at least a part of a central portion of k-space is acquired for each k-space subset; with the k-space subsets being k-space blades that are rotated about the centre of k-space, so that the total acquired data set of MR signals spans a circle in k-space,
c) reconstructing single-subset low resolution MR image from central k-space data of each k-space subset;
d) identifying image regions containing artefacts are in the single-subset low resolution MR images and derive weighting factors from the spatial distribution of image artefacts in the single-subset images the weighting factors reducing weighting of the voxel values of the single-subset images in the image regions containing artefacts;
e) combining the single-subset low resolution MR images into low-resolution MR image by the weighted superposition of the single-subset MR images according to said weighting factors;
f) combining the k-space subsets into a full k-space dataset;
g) combining the full k-space data set with a k-space representation of the low-resolution MR image into a combined full k-space data set; and
h) reconstructing a final image from the combined full k-space dataset.

8. A magnetic resonance (MR) device for carrying out the method claimed in claim 1, which MR device includes at least one main magnet coil for generating a uniform, steady magnetic field B0 within an examination volume, a number of gradient coils for generating switched magnetic field gradients in different spatial directions within the examination volume, at least one RF coil for generating RF pulses within the examination volume and/or for receiving MR signals from a body of a patient positioned in the examination volume, a control unit for controlling the temporal succession of RF pulses and switched magnetic field gradients, and a reconstruction unit for reconstructing MR images from the received MR signals, wherein the MR device is configured to perform the following steps:
a) generating MR signals by subjecting at least a portion of the body to a PROPELLER MR imaging sequence of at least one RF pulse and switched magnetic field gradients;
b) acquiring the MR signals as a plurality of k-space subsets, each k-space subset covering a different portion of k-space, wherein at least a part of a central portion of k-space is acquired for each k-space subset; with the k-space subsets being k-space blades that are rotated about the centre of k-space, so that the total acquired data set of MR signals spans a circle in k-space,
c) reconstructing single-subset MR images from each k-space subset;
d) identifying image regions containing artefacts are in the single-subset MR images and deriving weighting factors from the spatial distribution of image artefacts in the single-subset images the weighting factors reducing weighting of the voxel values of the single-subset images in the image regions containing artefacts; and
e) combining the single-subset MR images into a final MR image by weighted superposition using said weighting factors of the single-subset MR images.

9. A computer program to be run on a magnetic resonance (MR) device, which computer program comprises instructions for:
a) generating MR signals by subjecting at least a portion of the body to a PROPELLER MR imaging sequence of at least one RF pulse and switched magnetic field gradients;
b) acquiring the MR signals as a plurality of k-space subsets, each k-space subset covering a different portion of k-space, wherein at least a part of a central portion of k-space is acquired for each k-space subset; with the k-space subsets being k-space blades that are rotated about the centre of k-space, so that the total acquired data set of MR signals spans a circle in k-space,
c) reconstructing single-subset MR images from each k-space subset;
d) identifying image regions containing artefacts are in the single-subset MR images and deriving weighting factors from the spatial distribution of image artefacts in the single-subset images the weighting factors reducing weighting of the voxel values of the single-subset images in the image regions containing artefacts;
and
e) combining the single-subset MR images into a final MR image by weighted superposition using said weighting factors of the single-subset MR images.
